(19) United States
(12) Patent Application Publication
(10) Pub. No.: US 2025/0212309 A1
(43) Pub. Date: Jun. 26, 2025

(54) MEASUREMENT SYSTEM FOR A BIPOLAR HIGH VOLTAGE GENERATOR

(71) Applicant: Siemens Healthineers AG, Forchheim (DE)

(72) Inventor: Leander STURM, Mistelgau (DE)

(73) Assignee: Siemens Healthineers AG, Forchheim (DE)

(21) Appl. No.: 18/985,572

(22) Filed: Dec. 18, 2024

(30) Foreign Application Priority Data
Dec. 21, 2023 (EP) 23219214.6

(51) Int. Cl. H05G 1/26; H05G 1/32

(52) U.S. Cl. CPC H05G 1/265; H05G 1/32

(57) ABSTRACT

A measurement system for a bipolar high voltage generator, comprising: a first measuring channel to acquire a negative tube current and a negative tube voltage; a second measuring channel to acquire a positive tube current and a positive tube voltage; an interface between the first measuring channel and the second measuring channel, the interface being configured to transmit (i) first measured values of the negative tube current and the negative tube voltage, acquired via the first measuring channel, and/or (ii) second measured values of the positive tube current and the positive tube voltage, acquired via the second measuring channel; and a control logic to receive the first measured values and the second measured values, compare the received measured values with at least one limit value, and output a control signal as a function of a limit value violation occurring during the comparison of the received measured values.

### CROSS-REFERENCE TO RELATED APPLICATION(S)

The present application claims priority under 35 U.S.C. § 119 to European Patent Application No. 23219214.6, filed Dec. 21, 2023, the entire contents of which is incorporated herein by reference.

### FIELD

One or more example embodiments of the present invention relate to a measurement system for a bipolar high voltage generator, the bipolar high voltage generator, an X-ray tube, a method for outputting a control signal via a measurement system and an associated non-transitory computer program product.

### BACKGROUND

High voltage generators typically generate high voltages for operating conventional X-ray tubes. In X-ray tubes, high voltage is used to accelerate electrons from a cathode towards an anode, in order to generate X-rays when the accelerated electrons interact with the anode.

X-ray tubes may be categorized in particular according to whether one of the two electrodes, the anode or the cathode, is at frame potential. In this case, the X-ray tube is a unipolar X-ray tube.

If high voltage of opposite polarity is applied to both electrodes, the anode and the cathode, the X-ray tube is a bipolar X-ray tube. In particular, such a bipolar X-ray tube requires a bipolar high voltage generator that is configured to generate a negative tube current, a negative tube voltage, a positive tube current and a positive tube voltage, and to provide these in pairs at a negative high voltage output and at a positive high voltage output.

Due to the high voltages used, high voltage generators and/or X-ray tubes, in particular when used as medical electrical equipment, must generally be designed in accordance with regulatory requirements, in particular IEC and/or DIN standards. For example, IEC 60601-1 clause 4.7 basically provides for a single fault condition for medical electrical equipment. Accordingly, a medical electrical device must not pose a risk in the event of a single fault. For this class of equipment, high voltage generators and/or X-ray tubes, monitoring the tube voltage and tube current is particularly useful for this purpose.

The inventor is aware of a single channel approach for the single fault safe detection of tube voltage and tube current as the prior art. In this case, the tube voltage and tube current are typically processed in analog form and digitized via an analog-digital converter in a control logic, before the digitized measured values are evaluated for one channel in a setpoint comparison.

Such a single channel measurement system typically requires additional measures to ensure the prescribed single fault safety. In particular, a self-test of the measuring sections via error injection, monitoring of the functionally relevant supply voltages, monitoring of the component temperature of relevant components and/or an external watchdog module for monitoring the micro-controller may be implemented as part of the single channel measurement system.

### SUMMARY

At least one object of one or more embodiments of the present invention is to specify a measurement system for a bipolar high voltage generator, the bipolar high voltage generator, an X-ray tube, a method for outputting a control signal via a measurement system and an associated non-transitory computer program product with low complexity.

The object is achieved by the features of the independent claims. Advantageous embodiments are described in the dependent claims.

Independent of the grammatical term usage, individuals with male, female or other gender identities are included within the term.

The measurement system, according to an embodiment of the present invention, for a bipolar high voltage generator, wherein the bipolar high voltage generator is designed to generate a negative tube current, a negative tube voltage, a positive tube current and a positive tube voltage, the measurement system has
a first measuring channel for acquisition of the negative tube current and the negative tube voltage,
a second measuring channel for acquisition of the positive tube current and the positive tube voltage, characterized by
an interface between the first measuring channel and the second measuring channel, the interface being designed to transmit first measured values of the negative tube current and the negative tube voltage, acquired via the first measuring channel, and/or second measured values of the positive tube current and the positive tube voltage, acquired via the second measuring channel,
a control logic for receiving the first measured values and the second measured values,
wherein the control logic is configured to compare the received measured values with at least one limit value,
wherein the control logic is configured to output a control signal as a function of a limit value violation occurring during the comparison of the received measured values.

The method, according to an embodiment of the present invention, for outputting a control signal via the measurement system, according to an embodiment of the present invention, comprises the steps:
acquisition of a negative tube current and a negative tube voltage via a first measuring channel of the measurement system,
acquisition of a positive tube current and a positive tube voltage via a second measuring channel of the measurement system,
transmitting of the first measured values of the negative tube current and the negative tube voltage recorded via the first measuring channel and/or of the second measured values of the positive tube current and the positive tube voltage recorded via the second measuring channel via an interface of the measurement system,
receiving the first measured values and the second measured values via a control logic of the measurement system, -comparing the received measured values with at least one limit value via the control logic,
outputting a control signal via the control logic as a function of a limit value violation that occurred during the comparison of the received measured values.

One advantage of an embodiment of the present invention is that the additional measures required in the prior art, in particular, may be dispensed with at least in part and depending on embodiments of the present invention entirely. This reduces the complexity of the measurement system and/or the acquisition of the tube current and/or the tube voltage.

In particular, no typically complex self-test circuit and/or no independent watchdog module is required.

Alternatively or additionally, supply voltage monitoring is not required.

Another advantage of an embodiment of the present invention is that, compared to the prior art, fault detection is extended. In particular, the origin of a fault may be localized and/or assigned to certain components of the high voltage generator. For example, a fault in a high voltage divider may be detected via the tube voltage and/or in a measuring resistor via the tube current.

The lower complexity is accompanied by an altogether higher robustness of the measurement system and/or during acquisition of the tube current and/or the tube voltage. In particular, the measurement system may be less expensive due to its lower complexity.

The measurement system is configured for a bipolar high voltage generator. In principle, the measurement system according to one or more embodiments of the present invention may also be used for a unipolar high voltage generator. In the latter case, the unipolar high voltage generator is equipped in particular with a redundant tube current and tube voltage acquisition system, wherein the first measuring channel and the second measuring channel acquire the same measured variables. Alternatively, it is conceivable that the tube current and the tube voltage are measured via a single measuring channel and then evaluated in two measuring channels.

The bipolar high voltage generator, according to an embodiment of the present invention, is designed to generate a negative tube current, a negative tube voltage, a positive tube current and a positive tube voltage and has
a measurement system according to an embodiment of the present invention,
a negative high voltage output, at which the negative tube current and the negative tube voltage may be provided,
a positive high voltage output, at which the positive tube current and the positive tube voltage may be provided,
wherein the first measuring channel is connected to the negative high voltage output for acquisition of the negative tube current and the negative tube voltage,
wherein the second measuring channel is connected to the positive high voltage output for acquisition of the positive tube current and the positive tube voltage.

In particular, the bipolar high voltage generator may generate high voltages between 20 and 150 kV. For example, the negative tube voltage is-75 kV and the positive tube voltage is +75 kV. In particular, the negative tube voltage and the positive tube voltage are DC voltages.

The bipolar high voltage generator may comprise a high voltage unit for generating tube currents and/or tube voltages. The high voltage unit may comprise a first secondary-side transformer winding with a downstream rectifier for generating the negative tube voltage and a second secondary-side transformer winding with a downstream rectifier for generating the positive tube voltage. One output of the rectifier for the negative tube voltage typically forms the negative high voltage output. One output of the rectifier for the positive tube voltage typically forms the positive high voltage output.

A first primary-side transformer winding and/or a second primary-side transformer winding of the high voltage unit is supplied in particular by an inverter. The inverter signal for controlling the inverter may be generated and/or output by the control logic, for example.

The provision of the positive tube current and negative tube current at the high voltage outputs comprises, in particular, that a tube current at the positive tube voltage may emanate from the positive high voltage output and that essentially this tube current at the negative tube voltage may enter the negative high voltage output. In particular, the positive tube current and the negative tube current flow in the same circuit through the X-ray tube as a load and have a different polarity with respect to the high voltage generator. Ideally, in particular, the negative tube current corresponds to the positive tube current and/or the negative tube voltage corresponds to the positive tube voltage.

In particular, the term high voltage output is synonymous with the term high voltage contact. The high voltage outputs of the bipolar high voltage generator may, in particular, be designed as high voltage sockets or high voltage terminals.

The X-ray tube, according to an embodiment of the present invention, has
the bipolar high voltage generator according to an embodiment of the present invention,
an evacuated enclosure,
a cathode and
an anode,
wherein the cathode and the anode are arranged inside the evacuated enclosure,
wherein the anode is connected to the positive high voltage output and
wherein the cathode is connected to the negative high voltage output.

The X-ray tube assembly in particular has an electron emitter, which is arranged opposite the cathode side of the anode. The electron emitter may be a thermionic or a cold field emitter. In particular, field-effect emitters are cold-field emitters, unlike thermionic emitters, which generate electrons by heating the electron emitter.

In particular, an accelerating voltage is applied between the cathode and the anode, which is composed of the positive tube voltage and the negative tube voltage. In particular, the negative tube voltage is applied to the cathode and the positive tube voltage to the anode. The accelerating voltage causes the electrons emitted by the cathode to accelerate in the direction of the anode. The X-rays generated during the interaction with the anode have X-ray photons that have a maximum energy equal to the accelerating voltage times the elementary charge e.

The anode may be a rotating anode or a stationary anode. It is conceivable that the anode rotates together with or independently of the evacuated enclosure.

The evacuated enclosure in particular comprises a high vacuum and/or in particular may be a glass enclosure or a metal enclosure. In particular, if the X-ray tube has an evacuated metal enclosure, a small proportion of the electrons emitted at the cathode may discharge via the metal enclosure. In this case, the metal enclosure is connected to frame potential, for example. For example, the circuit to the high voltage generator is closed via the ground connection of the high voltage generator. The magnitude of the tube current flowing through the anode is in this case different from the magnitude of the tube current flowing through the cathode. In particular, the bipolar high voltage generator provides a positive tube current and a negative tube current, which differ in magnitude. In this case, the bipolar high voltage generator is operated asymmetrically.

The measurement system has, in particular, the first measuring channel, the second measuring channel, the interface and the control logic. The measurement system is, in particular, a circuit arrangement with electronic components that form the first measuring channel, the second measuring channel, the interface and the control logic.

The first measuring channel and the second measuring channel may, in principle, be structured identically. The first measuring channel and the second measuring channel differ particularly in the way they are connected to the bipolar high voltage generator in order to be able to acquire the respective measured values. Preferably, the first measuring channel and the second measuring channel differ only in the wiring to the bipolar high voltage generator. For example, the first measuring channel is basically configured to additionally or alternatively acquire the positive tube current and the positive tube voltage, while the second measuring channel may be configured to additionally or alternatively acquire the negative tube current and the negative tube voltage.

The first measuring channel and the second measuring channel are in particular designed with independent circuitry. The components of the first measuring channel and the components of the second measuring channel are, in particular, constructed and/or are present in each case separately from each other. The first measuring channel and the second measuring channel are connected to each other in a way that allows them to communicate with each other exclusively via the interface.

The following statements regarding the first measuring channel, the negative tube current and the negative tube voltage, also apply to the second measuring channel, the positive tube current and the positive tube voltage.

The first measuring channel in particular has a voltmeter for acquisition of the negative tube voltage. The voltmeter may in particular comprise a high voltage divider.

The first measuring channel in particular has an ammeter for acquisition of the negative tube current. The ammeter may in particular comprise a measuring resistor.

The negative tube voltage may in particular be acquired in a time-resolved manner. The negative tube current may in particular be acquired in a time-resolved manner. In particular, the first measured values may be time-resolved.

The first measuring channel is in particular designed with runtime capability. The first measuring channel is particularly capable of acquiring the first measured values during operation of the bipolar high voltage generator true to runtime. The first measuring channel may, in particular, monitor the negative tube current and/or the negative tube voltage in real time. A delay in the acquisition of the first measured values is ideally merely due to runtime.

The acquisition of the negative tube current and/or the negative tube voltage comprises, in particular, a measurement of the negative tube current via the ammeter and/or the negative tube voltage via the high voltage divider. The acquired negative tube current measured values form a first part of the first measured values. The acquired positive tube voltage measured values form a second part of the first measured values. The first measured values may consist of the tube current measured values and the tube voltage measured values.

The acquisition of the negative tube current and/or the negative tube voltage may comprise analog-to-digital conversion of acquired measured values. The first measuring channel may have an analog-digital converter for this purpose.

The acquisition of the negative tube current and/or the negative tube voltage may include conditioning and/or filtering acquired measured values. The first measuring channel may have a filter for conditioning and/or filtering the acquired measured values.

The first measuring channel comprises in particular a first acquisition path. The acquisition of the negative tube current and/or the negative tube voltage may include transferring the acquired measured values via the first acquisition path, in particular to the control logic and/or the interface.

The interface between the first measuring channel and the second measuring channel is, in particular, a digital interface. The interface may be designed in particular for asynchronous or synchronous and serial or parallel communication. In particular, communication between the first measuring channel and the second measuring channel may be carried out according to an UART or SPI standard.

The interface may essentially be designed to be unidirectional or bidirectional. In any case, the interface is designed in such a way that the acquired measured values of a measuring channel may be transmitted to the other respective measuring channel using a control logic. If the interface is designed to transmit both the first measured values and the second measured values, the interface is typically designed to be bidirectional.

The transmission comprises, in particular, sending and receiving the acquired measured values and/or is carried out, in particular, via a coupling unit. The acquired measured values are sent in particular via a decoupling unit. Receiving is performed in particular via an incoupling unit.

The interface may have one interface channel or a plurality of interface channels, for example. The interface channel may be designed to be unidirectional or bidirectional. Two of the plurality of interface channels may be designed to be unidirectional with opposing transmission directions. It is conceivable that at least one of the plurality of interface channels is bidirectional.

The first measuring channel may have a first incoupling unit and/or a first decoupling unit, with the interface being connected to the first incoupling unit and/or the second decoupling unit. In particular, the first incoupling unit and the first decoupling unit form a first coupling unit of the first measuring channel. The second measuring channel may comprise a second incoupling unit and/or a second decoupling unit, with the interface being connected to the second incoupling unit and/or the second decoupling unit. The second incoupling unit and the second decoupling unit in particular form a second coupling unit of the first measuring channel.

Typically, an interface channel is connected to a coupling unit, in particular a decoupling unit, of one measuring channel and to a coupling unit, in particular an incoupling unit, of the other measuring channel. It is conceivable that the first incoupling unit, the first decoupling unit, the second incoupling unit, the second decoupling unit and the interface channels in between form the interface.

The control logic may be connected directly to the first acquisition path or indirectly via the interface. The control logic may receive and/or pick up the first measured values and the second measured values at an input interface. In particular, the input interface may have at least four inputs. The four inputs may typically consist of a negative tube current input for the negative tube current measured value, a negative tube voltage input for the negative tube voltage measured value, a positive tube current input for the positive tube current measured value, and a positive tube voltage input for the positive tube voltage measured value.

The control logic may in particular comprise a logic module and/or a micro-controller and/or a processor. The control logic in particular has a memory in which program code, program code instructions and/or program code means may be stored. For the execution of the program code, the program code may be ideally retrieved from the memory. In particular, mapping of the comparison and/or output of the control signal takes place in the program code. Alternatively or additionally, the comparison and/or the output of the control signal may be mapped in logic modules of the logic block. In particular, the control logic forms a computing unit of the measurement system. The control logic is in particular a monitoring module of the measurement system.

The control logic may condition and/or filter the measured values in particular before and/or after comparison. The conditioning may in particular include forming a sum and/or forming a mean and/or integrating and/or adding and/or subtracting and/or multiplying and/or dividing two, three or all measured values. In particular, filtering may comprise smoothing of the measured values.

In particular, the control logic may compare the received measured values serially and/or in parallel. In particular, the control logic may compare time-resolved measured values.

Comparing comprises, in particular, performing one or more comparison operations. In particular, a comparison operation comprises at least one mathematical operation on at least one measured value and a further value, which may also be another measured value or a constant or the at least one limit value. The result of the comparison operation is, in particular, a limit value violation or limit value compliance.

The at least one limit value, for example, is stored in the memory and/or may be retrieved. It is conceivable that the memory unit is designed to compare the received measured values with several limit values. In particular, a single measured value may be compared with one or more limit values. The at least one limit value may in particular be a tube current limit value, a tube voltage limit value and/or a power limit value. Typically, two, preferably all, of the measured values received are compared with the at least one limit value or a plurality of limit values.

The measured values acquired are in particular actual values. The at least one limit value is in particular a target value. Typically, each actual value is compared with an associated target value. In particular, the tube current limit value, tube voltage limit value, and/or power limit values may be target values.

In particular, comparison using the control logic comprises determining whether the compared measured value complies with or violates the at least one limit value. Compliance with the at least one limit value may signify the exceeding or undershooting of the at least one limit value.

Violation of the at least one limit value may signify the undershooting or exceeding of the at least one limit value. For example, exceeding the at least one limit value is considered a limit value violation if the at least one limit value defines an upper limit. For example, undershooting the at least one limit value is considered a limit value violation if the at least one limit value defines a lower limit. Comparison using the control logic may be carried out with an absolute value of the received measured value and/or a signed measured value.

The control logic is designed to distinguish between a limit value violation when comparing the received measured values and compliance with the limit value when comparing the received measured values. Advantageously, the control logic has binary signal paths, whereby automatically and/or immediately and/or directly only the one signal path is activated in the event of a limit value violation and only the other signal path is activated when the limit value is complied with.

The control logic in particular has an output interface for outputting the control signal. The control signal differs in particular when a limit value is exceeded compared to when it is complied with. The control signal may vary depending on the type of measurement, in particular whether this is tube current or tube voltage or power. In particular, the control signal may provide a differentiated representation of the degree to which the limit value is exceeded. Outputting the control signal comprises, in particular, transmitting the control signal to, for example, the high voltage generator and/or the X-ray tube and/or an audiovisual output signal.

One embodiment provides that the measurement system also has a further control logic for receiving the first measured values and the second measured values, wherein the interface is configured to transmit the first measured values from the first measuring channel to the further control logic and to transmit the second measured values from the second measuring channel to the control logic, wherein the further control logic is designed to compare the received measured values with a limit value, wherein the further control logic is designed to output a control signal as a function of a limit value violation occurring during the comparison of the received measured values.

The above statements on the structure and function of the control logic apply equally to the further control logic. According to an embodiment of the present invention, the control logic and the further control logic differ in that the control logic is at the end of the first acquisition path of the first measuring channel and the further control logic is at the end of the second acquisition path of the second measuring channel. In this case, the first acquisition path forwards the first measured values directly to the control logic and the second acquisition path forwards the second measured values directly to the further control logic. Thus, the first measuring channel and the control logic form a first independent measuring circuit and the second measuring channel and the further control logic form a second independent measuring circuit. Advantageously, the first measuring circuit and the second measuring circuit are directly connected only via the interface. The first independent measuring circuit may be referred to herein as a first independent measuring unit, first independent measuring area or first independent measuring section. The second independent measuring circuit may be referred to herein as a second independent measuring unit, second independent measuring area or second independent measuring section.

One advantage of this embodiment is that, due to the redundancy of the first measuring circuit and the second measuring circuit, a single fault safe detection of faults in the high voltage generator is made possible. In particular, a fault in a high voltage divider and/or in a measuring resistor may be detected in a single fault free manner.

This advantage is achieved in particular by the first measuring circuit, in particular the first measuring channel and the control logic, and the second measuring circuit, in particular the second measuring channel and the further control logic, being configured independently of each other and/or redundantly in the measurement system. Furthermore, the measured values acquired by one measuring channel are transmitted to the other measuring channel via the interface, so that each measuring circuit may compare the measured values independently of each other and/or output the control signal.

One embodiment provides that the at least one limit value defines a tolerance band, wherein the tolerance band is set in such a way that it includes a deviation of the first measured values from the second measured values greater than zero and in particular less than 50%, in order to enable an asymmetric operation of the bipolar high voltage generator. The limit value violation of a tolerance band means that the compared measured value is outside the tolerance band. The limit value compliance with the tolerance band means that the compared measured value is within the tolerance band.

One embodiment provides that a comparison operation is performed during the comparison, wherein the one comparison operation specifies a subtraction of a product of the first measured values and a product of the second measured values, wherein the product difference is compared to the at least one limit value. This embodiment is particularly advantageous for defining and/or detecting a degree of asymmetry across the power comparison according to the product of tube current and tube voltage.

One embodiment provides that a different comparison operation is carried out during the comparison, wherein the other comparison operation specifies a comparison of the acquired measured values of the negative tube current and/or the positive tube current with a tube current limit value. This embodiment is particularly advantageous because a deviation with respect to the tube current may be set and/or detected.

One embodiment provides that a further comparison operation is carried out during the comparison, wherein the further comparison operation specifies a comparison of the acquired measured values of the negative tube voltage and/or the positive tube voltage with a tube voltage limit value. This embodiment is particularly advantageous because a deviation with respect to the tube voltage may be set and/or detected.

One embodiment provides that the compared measured values are output as part of the control signal. In this case, in particular the control signal may be transmitted to a control unit in addition to or as an alternative to the X-ray tube or high voltage generator. For example, in order to enable logging of the measured values. Alternatively or additionally, the control unit may adjust the operation of the high voltage generator and/or the X-ray tube depending on the measured values transmitted.

One embodiment provides that the control signal is designed and the measurement system is connected to a bipolar high voltage generator in such a way that outputting the control signal causes a bipolar high voltage generator to switch off. This embodiment is particularly advantageous because the bipolar high voltage generator may be switched off in the event of a limit value being exceeded. For example, directly via the control signal from the control logic and/or via the control unit to which the control signal is transmitted from the control logic.

One embodiment provides that when the bipolar high voltage generator is switched off via the control signal, an inverter of the bipolar high voltage generator is switched off. For example, the control signal may instruct the inverter to switch off.

The non-transitory computer program product may be a computer program or comprise a computer program. The computer program product in particular has the program code, program code instructions and/or program code means which map the method steps according to an embodiment of the present invention. This means that the method according to an embodiment of the present invention may be defined and carried out in a repeatable manner, and control may be exercised over any disclosure of the method according to embodiments of the present invention. The computer program product is preferably configured in such a way that the computing unit may carry out the method steps according to an embodiment of the present invention via the computer program product. The program code may be loaded into a memory of the computing unit in particular and typically executed via a processor of the computing unit with access to the memory. When the computer program product, in particular the program code, is executed in the computing unit, all the embodiments of the method described that are based on an embodiment of the present invention may typically be carried out. For example, the computer program product is stored on a physical, computer-readable medium and/or digitally as a data packet on a computer network. The computer program product may be the physical computer-readable medium and/or the data packet on the computer network. Thus, an embodiment of the present invention may also be based on the physical, non-transitory, computer-readable medium and/or the data packet in the computer network. The physical, computer-readable medium may usually be connected directly to the computing unit, for example by inserting the physical, computer-readable medium into a DVD drive or plugging it into a USB port, which allows the computing unit read access in particular to the physical, computer-readable medium. Preferably the data packet may be retrieved from the computer network. The computer network may have the computing unit or be indirectly connected to the computing unit via a wide-area network (WAN) or a (wireless) local-area network (WLAN or LAN) connection. For example, the computer program product may be stored digitally on a cloud server at a computer network storage location, transferred via the WAN over the Internet and/or via WLAN or LAN to the computing unit in particular by accessing a download link that refers to the storage location of the computer program product.

Features, advantages or alternative embodiments mentioned in the description of the apparatus must also be applied to the method and vice versa. In other words, method claims may be further developed to include apparatus features and vice versa. In particular, the apparatus according to an embodiment of the present invention may be used in the method.

### BRIEF DESCRIPTION OF THE DRAWINGS

The present invention is described and explained in more detail below on the basis of the exemplary embodiments shown in the figures. Generally, in the following description of the figures, the same reference symbol is used for the same structures and units as in the first occurrence of the respective structure or unit.

These show as follows:

FIG. 1 a measurement system for a bipolar high voltage generator,

FIG. 2 the measurement system in a first embodiment,

FIG. 3 a method for outputting a control signal via a measurement system,

FIG. 4 the method in a first embodiment,

FIG. 5 the method in a second embodiment and

FIG. 6 the method in a third embodiment.

### DETAILED DESCRIPTION

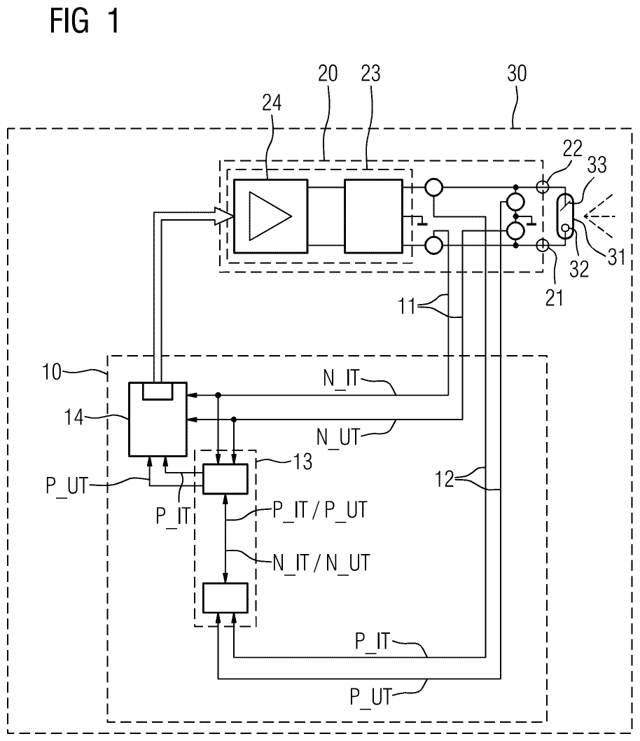

FIG. 1 shows a measurement system, according to an embodiment of the present invention, for a bipolar high voltage generator in a block diagram.

The measurement system 10 is shown in FIG. 1 as part of a bipolar high voltage generator 20. The bipolar high voltage generator 20 is designed to generate a negative tube current N_IT, a negative tube voltage N_UT, a positive tube current P_IT and a positive tube voltage P_UT. The bipolar high voltage generator 20 further comprises a negative high voltage output 21 and a positive high voltage output 22. The negative tube current N_IT and the negative tube voltage N_UT may be provided at the negative high voltage output 21. The positive tube current P_IT and the positive tube voltage P_UT may be provided at the positive high voltage output 22.

The bipolar high voltage generator 20 also has a high voltage unit 23 for generating the tube currents N_IT, P_IT and the tube voltages N_UT, P_UT. The high voltage unit 23 has an inverter 24.

The measurement system 10 has a first measuring channel 11 for acquisition of the negative tube current N_IT and the negative tube voltage N_UT and a second measuring channel 12 for acquisition of the positive tube current P_IT and the positive tube voltage P_UT. The first measuring channel 11 is connected to the negative high voltage output 21. The second measuring channel 12 is connected to the positive high voltage output 22.

The measurement system 10 also has an interface 13 between the first measuring channel 11 and the second measuring channel 12. The interface 13 is designed to transmit first measured values of the negative tube current N_IT and the negative tube voltage N_UT acquired via the first measuring channel 11, and/or second measured values of the positive tube current P_IT and the positive tube voltage P_UT acquired via the second measuring channel 12.

The measurement system 10 also has a control logic 14 for receiving the first measured values and the second measured values. The control logic 14 is designed to compare the received measured values with at least one limit value. The control logic 14 is designed to output a control signal depending on a limit value violation that occurs when comparing the received measured values.

The high voltage generator 20 is shown in FIG. 1 as part of an X-ray tube 30. The X-ray tube 30 also has an evacuated enclosure 31, a cathode 32 and an anode 33. The cathode 32 and the anode 33 are arranged within the evacuated enclosure 31. The anode 33 is connected to the positive high voltage output 22. The cathode 21 is connected to the negative high voltage output 21.

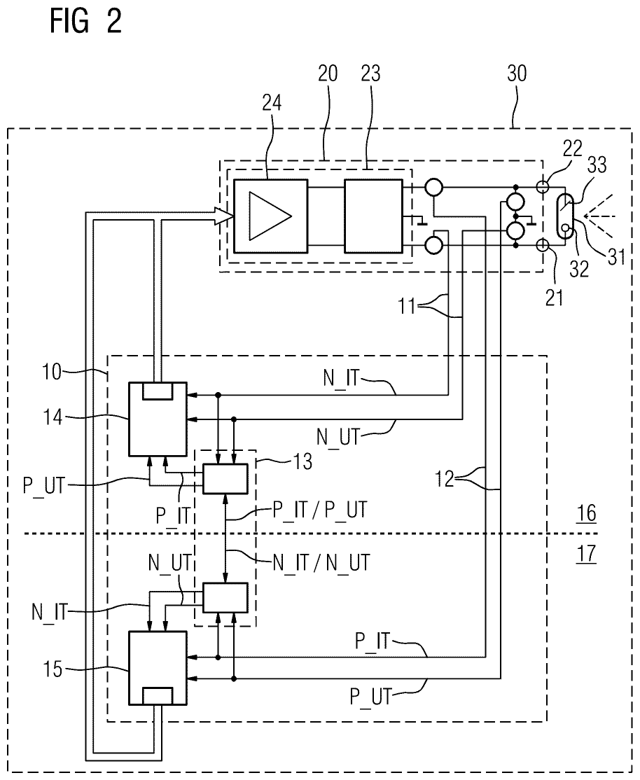

FIG. 2 shows a first exemplary embodiment of the measurement system 10 in a block diagram.

The measurement system 10 also has a further control logic 15 for receiving the first measured values and the second measured values. The interface 13 is configured to transmit the first measured values from the first measuring channel 11 to the further control logic 15 and to transmit the second measured values from the second measuring channel 12 to the control logic 14. The further control logic 15 is configured to compare the received measured values with a limit value. The further control logic 15 is configured to output a control signal as a function of a limit value violation occurring during the comparison of the received measured values.

In this embodiment the first measuring channel 11 and the control logic 14 form a first independent measuring circuit 16, and the second measuring channel 12 and the further control logic 15 form a second independent measuring circuit 17. The first measuring circuit 16 and the second measuring circuit 17 are directly connected only via the interface 13. In FIG. 2 the two measuring circuits 16, 17 are shown separated by the broken line.

Furthermore, in this exemplary embodiment, four digital-to-analog converters are used in the acquisition paths for the measured values N_IT, N_UT, P_IT, P_UT. According to a development the at least one limit value defines a tolerance band, wherein the tolerance band is set in such a way that it maps a deviation of the first measured values from the second measured values greater than zero and in particular less than 50%, in order to enable an asymmetric operation of the bipolar high voltage generator. The first measured values and/or the second measured values may in particular be time-resolved.

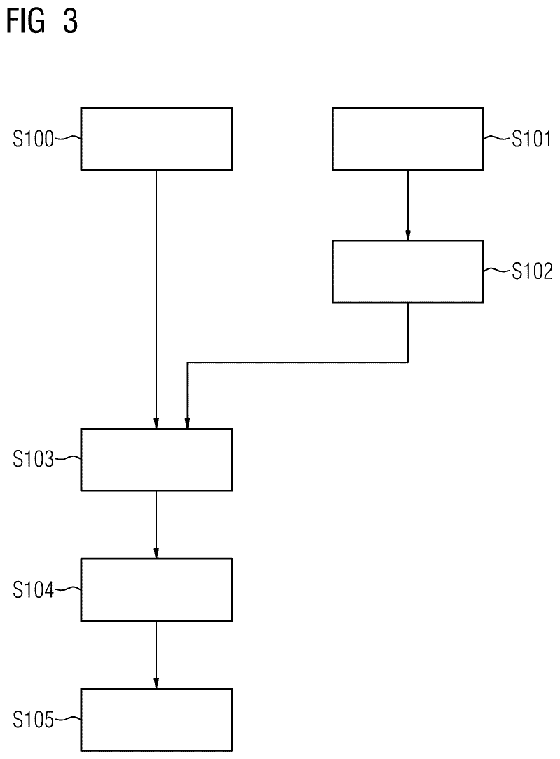

FIG. 3 shows a method for outputting a control signal via a measurement system in a flow diagram with method steps S100 to S105:

Method step S100 denotes the acquisition of a negative tube current N_IT and a negative tube voltage N_UT via a first measuring channel 11 of the measurement system 10.

Method step S101 denotes the acquisition of a positive tube current P_IT and a positive tube voltage P_UT via a second measuring channel 12 of the measurement system 10.

Method step S102 denotes the transmission of the second measured values of the positive tube current P_IT and the positive tube voltage P_UT acquired via the second measuring channel 12 via the interface 13 of the measurement system 10.

Method step S103 denotes the reception of the first measured values and the second measured values via a control logic 14 of the measurement system 10.

Method step S104 denotes a comparison of the received measured values with at least one limit value via the control logic 14.

Method step S105 denotes the outputting a control signal via the control logic 14 as a function of a limit value violation that occurred during the comparison of the received measured values.

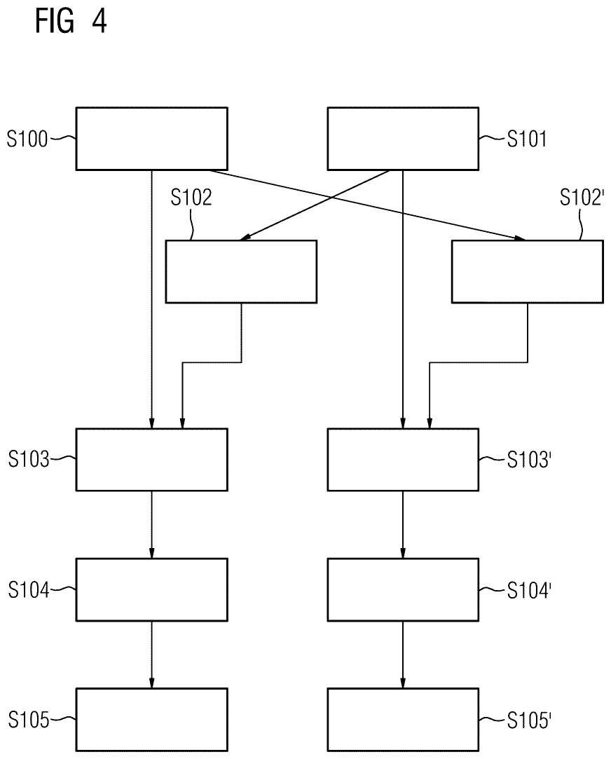

FIG. 4 shows a first exemplary embodiment of the method in a flow diagram.

Method step S102′ denotes the transmission of first measured values of the negative tube current N_IT and the negative tube voltage N_UT acquired via the first measuring channel 11 via an interface 13 of the measurement system 10.

Method step S103′ denotes the reception of the first measured values and the second measured values via a further control logic 15 of the measurement system 10.

Method step S104′ denotes a comparison of the received measured values with at least one limit value via the further control logic 15.

Method step S105′ denotes the outputting of a control signal via the further control logic 15 as a function of a limit value violation that occurred during the comparison of the received measured values.

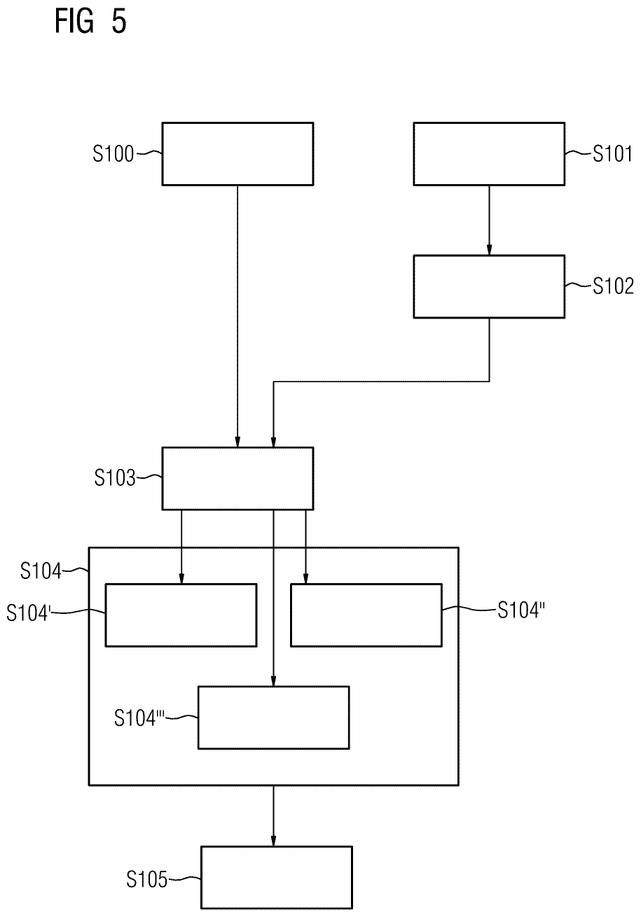

FIG. 5 shows a second exemplary embodiment of the method in a flow diagram.

Method step S104′ denotes how a comparison operation is performed during the comparison, wherein the one comparison operation specifies a subtraction of a product of the first measured values and a product of the second measured values, wherein the product difference is compared to the at least one limit value.

Method step S104″ denotes how a different comparison operation is carried out during the comparison, wherein the other comparison operation specifies a comparison of the acquired measured values of the negative tube current N_IT and/or the positive tube current P_IT with a tube current limit value.

Method step S104′″ denotes how a further comparison operation is carried out during the comparison, wherein the further comparison operation specifies a comparison of the acquired measured values of the negative tube voltage N_UT and/or the positive tube voltage P_UT with a tube voltage limit value.

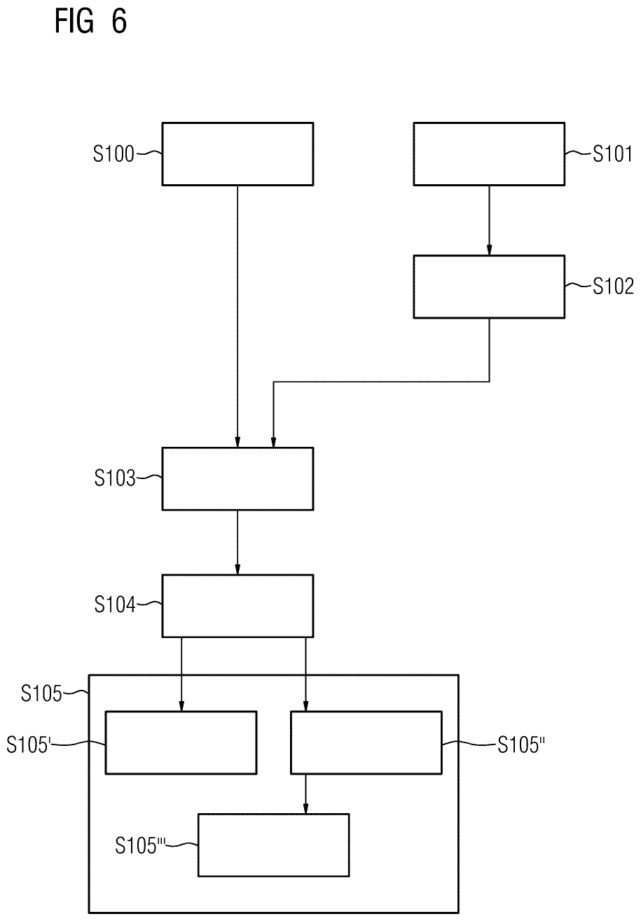

FIG. 6 shows a third exemplary embodiment of the method in a flow diagram.

Method step S105′ denotes how the compared measured values are output as part of the control signal.

Method step S105″ denotes how the control signal is designed and the measurement system is connected to a bipolar high voltage generator in such a way that outputting the control signal causes a bipolar high voltage generator to switch off.

Method step S105′″ denotes how when the bipolar high voltage generator is switched off via the control signal, an inverter of the bipolar high voltage generator is switched off.

It will be understood that, although the terms first, second, etc. may be used herein to describe various elements, components, regions, layers, and/or sections, these elements, components, regions, layers, and/or sections, should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items. The phrase “at least one of” has the same meaning as “and/or”.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” “beneath,” or “under,” other elements or features would then be oriented “above” the other elements or features. Thus, the example terms “below” and “under” may encompass both an orientation of above and below. The device may be otherwise oriented (rotated 90 degrees or at other orientations) and the spatially relative descriptors used herein interpreted accordingly. In addition, when an element is referred to as being “between” two elements, the element may be the only element between the two elements, or one or more other intervening elements may be present.

Spatial and functional relationships between elements (for example, between modules) are described using various terms, including “on,” “connected,” “engaged,” “interfaced,” and “coupled.” Unless explicitly described as being “direct,” when a relationship between first and second elements is described in the disclosure, that relationship encompasses a direct relationship where no other intervening elements are present between the first and second elements, and also an indirect relationship where one or more intervening elements are present (either spatially or functionally) between the first and second elements. In contrast, when an element is referred to as being “directly” on, connected, engaged, interfaced, or coupled to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Also, the term “example” is intended to refer to an example or illustration.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

It is noted that some example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed above. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Specific structural and functional details disclosed herein are merely representative for purposes of describing example embodiments. The present invention may, however, be embodied in many alternate forms and should not be construed as limited to only the embodiments set forth herein.

In addition, or alternative, to that discussed above, units and/or devices according to one or more example embodiments may be implemented using hardware, software, and/or a combination thereof. For example, hardware devices may be implemented using processing circuitry such as, but not limited to, a processor, Central Processing Unit (CPU), a controller, an arithmetic logic unit (ALU), a digital signal processor, a microcomputer, a field programmable gate array (FPGA), a System-on-Chip (SoC), a programmable logic unit, a microprocessor, or any other device capable of responding to and executing instructions in a defined manner. Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” of “displaying” or the like, refer to the action and processes of a computer system, or similar electronic computing device/hardware, that manipulates and transforms data represented as physical, electronic quantities within the computer system's registers and memories into other data similarly represented as physical quantities within the computer system memories or registers or other such information storage, transmission or display devices.

In this application, including the definitions below, the term ‘module’ or the term ‘controller’ may be replaced with the term ‘circuit.’ The term ‘module’ may refer to, be part of, or include processor hardware (shared, dedicated, or group) that executes code and memory hardware (shared, dedicated, or group) that stores code executed by the processor hardware.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

Software may include a computer program, program code, instructions, or some combination thereof, for independently or collectively instructing or configuring a hardware device to operate as desired. The computer program and/or program code may include program or computer-readable instructions, software components, software modules, data files, data structures, and/or the like, capable of being implemented by one or more hardware devices, such as one or more of the hardware devices mentioned above. Examples of program code include both machine code produced by a compiler and higher level program code that is executed using an interpreter.

For example, when a hardware device is a computer processing device (e.g., a processor, Central Processing Unit (CPU), a controller, an arithmetic logic unit (ALU), a digital signal processor, a microcomputer, a microprocessor, etc.), the computer processing device may be configured to carry out program code by performing arithmetical, logical, and input/output operations, according to the program code. Once the program code is loaded into a computer processing device, the computer processing device may be programmed to perform the program code, thereby transforming the computer processing device into a special purpose computer processing device. In a more specific example, when the program code is loaded into a processor, the processor becomes programmed to perform the program code and operations corresponding thereto, thereby transforming the processor into a special purpose processor.

Software and/or data may be embodied permanently or temporarily in any type of machine, component, physical or virtual equipment, or computer storage medium or device, capable of providing instructions or data to, or being interpreted by, a hardware device. The software also may be distributed over network coupled computer systems so that the software is stored and executed in a distributed fashion. In particular, for example, software and data may be stored by one or more computer readable recording mediums, including the tangible or non-transitory computer-readable storage media discussed herein.

Even further, any of the disclosed methods may be embodied in the form of a program or software. The program or software may be stored on a non-transitory computer readable medium and is adapted to perform any one of the aforementioned methods when run on a computer device (a device including a processor). Thus, the non-transitory, tangible computer readable medium, is adapted to store information and is adapted to interact with a data processing facility or computer device to execute the program of any of the above mentioned embodiments and/or to perform the method of any of the above mentioned embodiments.

Example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order.

According to one or more example embodiments, computer processing devices may be described as including various functional units that perform various operations and/or functions to increase the clarity of the description. However, computer processing devices are not intended to be limited to these functional units. For example, in one or more example embodiments, the various operations and/or functions of the functional units may be performed by other ones of the functional units. Further, the computer processing devices may perform the operations and/or functions of the various functional units without sub-dividing the operations and/or functions of the computer processing units into these various functional units.

Units and/or devices according to one or more example embodiments may also include one or more storage devices. The one or more storage devices may be tangible or non-transitory computer-readable storage media, such as random access memory (RAM), read only memory (ROM), a permanent mass storage device (such as a disk drive), solid state (e.g., NAND flash) device, and/or any other like data storage mechanism capable of storing and recording data. The one or more storage devices may be configured to store computer programs, program code, instructions, or some combination thereof, for one or more operating systems and/or for implementing the example embodiments described herein. The computer programs, program code, instructions, or some combination thereof, may also be loaded from a separate computer readable storage medium into the one or more storage devices and/or one or more computer processing devices using a drive mechanism. Such separate computer readable storage medium may include a Universal Serial Bus (USB) flash drive, a memory stick, a Blu-ray/DVD/CD-ROM drive, a memory card, and/or other like computer readable storage media. The computer programs, program code, instructions, or some combination thereof, may be loaded into the one or more storage devices and/or the one or more computer processing devices from a remote data storage device via a network interface, rather than via a local computer readable storage medium. Additionally, the computer programs, program code, instructions, or some combination thereof, may be loaded into the one or more storage devices and/or the one or more processors from a remote computing system that is configured to transfer and/or distribute the computer programs, program code, instructions, or some combination thereof, over a network. The remote computing system may transfer and/or distribute the computer programs, program code, instructions, or some combination thereof, via a wired interface, an air interface, and/or any other like medium.

The one or more hardware devices, the one or more storage devices, and/or the computer programs, program code, instructions, or some combination thereof, may be specially designed and constructed for the purposes of the example embodiments, or they may be known devices that are altered and/or modified for the purposes of example embodiments.

A hardware device, such as a computer processing device, may run an operating system (OS) and one or more software applications that run on the OS. The computer processing device also may access, store, manipulate, process, and create data in response to execution of the software. For simplicity, one or more example embodiments may be exemplified as a computer processing device or processor; however, one skilled in the art will appreciate that a hardware device may include multiple processing elements or processors and multiple types of processing elements or processors. For example, a hardware device may include multiple processors or a processor and a controller. In addition, other processing configurations are possible, such as parallel processors.

The computer programs include processor-executable instructions that are stored on at least one non-transitory computer-readable medium (memory). The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc. As such, the one or more processors may be configured to execute the processor executable instructions.

The computer programs may include: (i) descriptive text to be parsed, such as HTML (hypertext markup language) or XML (extensible markup language), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Haskell, Go, SQL, R, Lisp, Java®, Fortran, Perl, Pascal, Curl, OCaml, Javascript®, HTML5, Ada, ASP (active server pages), PHP, Scala, Eiffel, Smalltalk, Erlang, Ruby, Flash®, Visual Basic®, Lua, and Python®.

Further, at least one example embodiment relates to the non-transitory computer-readable storage medium including electronically readable control information (processor executable instructions) stored thereon, configured in such that when the storage medium is used in a controller of a device, at least one embodiment of the method may be carried out.

The computer readable medium or storage medium may be a built-in medium installed inside a computer device main body or a removable medium arranged so that it can be separated from the computer device main body. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

Shared memory hardware encompasses a single memory device that stores some or all code from multiple modules. Group memory hardware encompasses a memory device that, in combination with other memory devices, stores some or all code from one or more modules.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The apparatuses and methods described in this application may be partially or fully implemented by a special purpose computer created by configuring a general purpose computer to execute one or more particular functions embodied in computer programs. The functional blocks and flowchart elements described above serve as software specifications, which can be translated into the computer programs by the routine work of a skilled technician or programmer.

Although described with reference to specific examples and drawings, modifications, additions and substitutions of example embodiments may be variously made according to the description by those of ordinary skill in the art. For example, the described techniques may be performed in an order different with that of the methods described, and/or components such as the described system, architecture, devices, circuit, and the like, may be connected or combined to be different from the above-described methods, or results may be appropriately achieved by other components or equivalents.

Although the present invention has been illustrated and described in more detail by example embodiments, this shall nevertheless not limit the present invention to the disclosed examples and other variations may be deduced from these by the person skilled in the art without extending beyond the scope of protection of the present invention.

What is claimed is:

1. A measurement system for a bipolar high voltage generator, wherein the bipolar high voltage generator is configured to generate a negative tube current, a negative tube voltage, a positive tube current and a positive tube voltage, wherein the measurement system comprises:
a first measuring channel to acquire the negative tube current and the negative tube voltage;
a second measuring channel to acquire the positive tube current and the positive tube voltage;
an interface between the first measuring channel and the second measuring channel, the interface being configured to transmit at least one of (i) first measured values of the negative tube current and the negative tube voltage, acquired via the first measuring channel, or (ii) second measured values of the positive tube current and the positive tube voltage, acquired via the second measuring channel; and
a control logic configured to
receive the first measured values and the second measured values,
compare the first measured values and the second measured values with at least one first limit value, and
output a control signal as a function of a first limit value violation occurring during comparison of the first measured values and the second measured values with the at least one first limit value.

2. The measurement system as claimed in claim 1, further comprising:
a further control logic configured to receive the first measured values and the second measured values; wherein
the interface is configured to transmit the first measured values from the first measuring channel to the further control logic, and to transmit the second measured values from the second measuring channel to the control logic, and
the further control logic is configured to
compare the first measured values from the first measuring channel and the second measured values from the second measuring channel with a second limit value, and
output a control signal as a function of a second limit value violation occurring during comparison of the first measured values from the first measuring channel and the second measured values from the second measuring channel with the second limit value.

3. The measurement system as claimed in claim 2, wherein the first measuring channel and the control logic form a first independent measuring circuit and the second measuring channel and the further control logic form a second independent measuring circuit, and wherein the first independent measuring circuit and the second independent measuring circuit are directly connected only via the interface.

4. The measurement system as claimed in claim 1, wherein the at least one first limit value defines a tolerance band, wherein the tolerance band is set to map a deviation of the first measured values from the second measured values that is greater than zero to enable an asymmetric operation of the bipolar high voltage generator.

5. The measurement system as claimed in claim 1, wherein at least one of the first measured values or the second measured values are time-resolved.

6. A bipolar high voltage generator configured to generate a negative tube current, a negative tube voltage, a positive tube current and a positive tube voltage, the bipolar high voltage generator comprising:
the measurement system according to claim 1;
a negative high voltage output at which the negative tube current and the negative tube voltage are provided; and
a positive high voltage output at which the positive tube current and the positive tube voltage are provided; wherein
the first measuring channel is connected to the negative high voltage output to acquire the negative tube current and the negative tube voltage, and
the second measuring channel is connected to the positive high voltage output to acquire the positive tube current and the positive tube voltage.

7. An X-ray tube, comprising:
the bipolar high voltage generator as claimed in claim 6;
an evacuated enclosure;
a cathode; and
an anode; wherein
the cathode and the anode are arranged inside the evacuated enclosure,
the anode is connected to the positive high voltage output, and
the cathode is connected to the negative high voltage output.

8. A method for outputting a control signal via the measurement system as claimed in claim 1, the method comprising:
acquiring the negative tube current and the negative tube voltage via a first measuring channel of the measurement system;
acquiring the positive tube current and the positive tube voltage via the second measuring channel of the measurement system;
transmitting, via the interface of the measurement system, at least one of (i) the first measured values of the negative tube current and the negative tube voltage or (ii) the second measured values of the positive tube current and the positive tube voltage;
receiving, via the control logic of the measurement system, the first measured values and the second measured values;
comparing, via the control logic, the first measured values and the second measured values with at least one limit value; and
outputting, via the control logic, a control signal as a function of a limit value violation that occurred during comparison of the first measured values and the second measured values with the at least one limit value.

9. The method as claimed in claim 8, wherein a first comparison operation is performed during the comparing, wherein the first comparison operation specifies a subtraction of a product of the first measured values and a product of the second measured values to obtain a product difference, and wherein the product difference is compared to the at least one limit value.

10. The method as claimed in claim 8, wherein a comparison operation is performed during the comparing, wherein the comparison operation specifies a comparison of at least one of the first measured values of the negative tube current or the second measured values of the positive tube current with a tube current limit value.

11. The method as claimed in claim 8, wherein a comparison operation is performed during the comparing, wherein the comparison operation specifies a comparison of at least one of the first measured values of the negative tube voltage or the second measured values of the positive tube voltage with a tube voltage limit value.

12. The method as claimed in claim 8, wherein the first measured values and the second measured values are output as part of the control signal.

13. The method as claimed in claim 8, wherein the control signal is configured, and the measurement system is connected to the bipolar high voltage generator, such that outputting the control signal causes the bipolar high voltage generator to switch off.

14. The method as claimed in claim 13, wherein when the bipolar high voltage generator is switched off via the control signal, an inverter of the bipolar high voltage generator is switched off.

15. A non-transitory computer-readable storage medium storing computer-readable instructions that, when executed by a computing unit of a measurement system, cause the measurement system to perform the method of claim 8.

16. The measurement system as claimed in claim 4, wherein the tolerance band is set to map a deviation of the first measured values from the second measured values that is greater than zero and less than 50%.

17. The measurement system as claimed in claim 2, wherein the at least one first limit value defines a tolerance band, wherein the tolerance band is set to map a deviation of the first measured values from the second measured values that is greater than zero to enable an asymmetric operation of the bipolar high voltage generator.

18. The measurement system as claimed in claim 3, wherein the at least one first limit value defines a tolerance band, wherein the tolerance band is set to map a deviation of the first measured values from the second measured values that is greater than zero to enable an asymmetric operation of the bipolar high voltage generator.

19. The method as claimed in claim 9, wherein a second comparison operation is performed during the comparing, wherein the second comparison operation specifies a comparison of at least one of the first measured values of the negative tube current or the second measured values of the positive tube current with a tube current limit value.

20. The method as claimed in claim 19, wherein a third comparison operation is performed during the comparing, wherein the third comparison operation specifies a comparison of at least one of the first measured values of the negative tube voltage or the second measured values of the positive tube voltage with a tube voltage limit value.
